(19) United States
(12) Patent Application Publication
(10) Pub. No.: US 2007/0053527 A1
(43) Pub. Date: Mar. 8, 2007

(54) Audio output coordination

(75) Inventors: Mauro Barbieri, Eindhoven (NL); Igor Wilhelmus Francisc Paulussen, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONIC N.V., 5621 BA Eindhoven (NL)

(21) Appl. No.: 10/555,753

(22) PCT Filed: May 5, 2004
(86) PCT No.: PCT/IB04/50599

§ 371 Date: Nov. 4, 2005

(30) Foreign Application Priority Data
May 9, 2003 (EP) 03101291.7

(51) Int. Cl. H03G 3/00

(52) U.S. Cl. 381/104

(57) ABSTRACT

To control the sound output of various devices (1a, 1b, 1c, . . . ) a control unit (3) gathers information (I) on the sound output of the devices. Before a device starts producing sound, it submits a request (R) to the control unit. In response to the request, the control unit allocates a sound share (S) to the device on the basis of the sound information, the sound share involving a maximum volume. Thus the volume of any new sound is determined by the volume of the existing sound. An optional priority schedule may allow existing sound to be reduced in volume.

The present invention relates to audio output coordination. More in particular, the present invention relates to a method and a system for controlling the audio output of devices.

In a typical building, various devices are present which may produce sound. In a home, for example, an audio (stereo) set and/or a TV set may produce music, a vacuum cleaner and a washing machine may produce noise, while a telephone may be ringing. These sounds may be produced sequentially or concurrently. If at least some of the sounds are produced at the same time and at approximately the same location, they will interfere and one or more sounds may not be heard.

It has been suggested to reduce such sound interference, for example by muting a television set in response to an incoming telephone call. Various similar muting schemes have been proposed. U.S. Pat. No. 5,987,106 discloses an automatic volume control system and method for use in a multimedia computer system. The system recognizes an audio mute event notification signal, generated in response to an incoming telephone call, and selectively generates a control signal for muting or decreasing the volume to at least one speaker. This known system takes into account the location of the telephone, speakers and audio generating devices.

All these Prior Art solutions mute an audio source, such as a television set, in response to the activation of another audio source, such as a telephone. These solutions are one-way only in that they do not allow the telephone to be muted when the television set is switched on. In addition, the Prior Art solutions do not take into account the overall sound production but focus on a few devices only.

It is an object of the present invention to overcome these and other problems of the Prior Art and to provide a method and a system for controlling the audio output of devices which allows the audio output of substantially all devices concerned to be controlled.

Accordingly, the present invention provides a method of controlling the audio output of a first and at least one second device capable of producing sound, which devices are capable of exchanging information with a control unit, the method comprising the steps of:

the control unit gathering sound status information on at least the second devices;

the first device, prior to increasing its sound production, submitting a sound production request to the control unit;

the control unit, in response to the request, allocating a sound share to the first device; and

the first device producing sound in accordance with the allocated sound share, wherein the sound status information comprises the volume of the sound produced by the respective device, and wherein the sound share involves a maximum permitted sound volume.

That is, in the present invention the sound production of a device is determined by the sound share allocated to that particular device. The sound share comprises at least a maximum volume but may also comprise other parameters, such as duration and/or frequency range. In other words, a maximum volume and possibly other parameters are assigned to each device before it starts to produce sounds, or before it increases its sound production. The sound volume produced and the maximum sound volume allowed may also be indicated for a specific frequency range. Preferably, the sound production of each device is determined entirely by the respective allocated sound share, that is, the device is arranged in such a way that any substantial sound production over and above that determined by its sound share is not possible.

The allocation of a sound share is determined by a control unit on the basis of sound status information on at least the devices which are already producing sound and preferably all devices. This sound status information comprises at least the volume of the sound produced by the respective devices, but may also comprise ambient noise levels, the duration of the activity involving sound production, and other parameters. Using this sound status information, and possible other parameters such as the relative locations of the devices, the control unit assigns a sound share to the device which submitted the request.

The present invention is based upon the insight that various devices which operate in each others (acoustic) vicinity together produce a quantity of sound which can be said to fill a “sound space”. This sound space is defined by the total amount of sound that can be accepted at a certain location and at a certain point in time. Each sound producing device takes up a portion of that sound space in accordance with the sound share it was allocated. Any start or increase of sound production will have to match the sound share of that device, assuming that such a share had already been allocated. If no share has been allocated, the device must submit a sound request to the control unit.

In a preferred embodiment, the sound status information may further comprise an ambient noise level, at least one user profile and/or a frequency range. Additionally, or alternatively, the sound share may further involve a time duration and/or a frequency range.

It is noted that a sound share could be a “null” share: no sound production is allowed under the circumstances and effectively the sound request is denied. According to an important further aspect of the present invention, the device which submitted the sound request may then use an alternative output, for instance vibrations or light, instead of the sound. An alternative output may also be used when the allocated sound share is insufficient, for example when the allocated volume is less than the requested volume. In that case, both sound and an alternative output may be used.

In the embodiments discussed above the sound production of a device about to produce sound (labeled “first device”) is determined by the sound production of the other devices (labeled “second devices”), some of which may already be producing sound. According to an important further aspect of the present invention, the reverse may also be possible: in certain cases the sound production of the second devices may be adjusted in response to a sound request by the first device. To this end, at least one device may have a priority status, and an allocated sound share may be adjusted in response to a sound request from a device having priority status. In addition, several priority status levels may be distinguished.

In a preferred embodiment, the devices are connected by a communications network. Such a communications network may be a hard-wired network or a wireless network. In the latter case, Bluetooth®, IEEE 802.11 or similar wireless protocols may be employed. It will of course be understood that the actual protocol used has no bearing on the present invention.

Although a central control unit may be provided, embodiments can be envisaged in which each device has an individual control unit. In such embodiments, the individual control units exchange sound information and information relating to sound requests while the central control unit may be dispensed with.

The present invention further provides a system for use in the method defined above, the system comprising a first and at least one second device capable of producing sound, which devices are capable of exchanging information with a control unit, the system being arranged for:

the control unit gathering sound status information on at least the second devices;

the first device, prior to increasing its sound production, submitting a sound production request to the control unit;

the control unit, in response to the request, allocating a sound share to the first device; and

the first device producing sound in accordance with the allocated sound share, wherein the sound status information comprises the volume of the sound produced by the respective device, and wherein the sound share involves a maximum permitted sound volume.

The system preferably comprises a communications network for communication sound status information, sound production requests, sound shares and other information.

The present invention additionally provides a control unit for use in the method defined above, a software program for use in the control unit, as well as a data carrier comprising the software program.

The present invention will further be explained below with reference to exemplary embodiments illustrated in the accompanying drawings, in which:

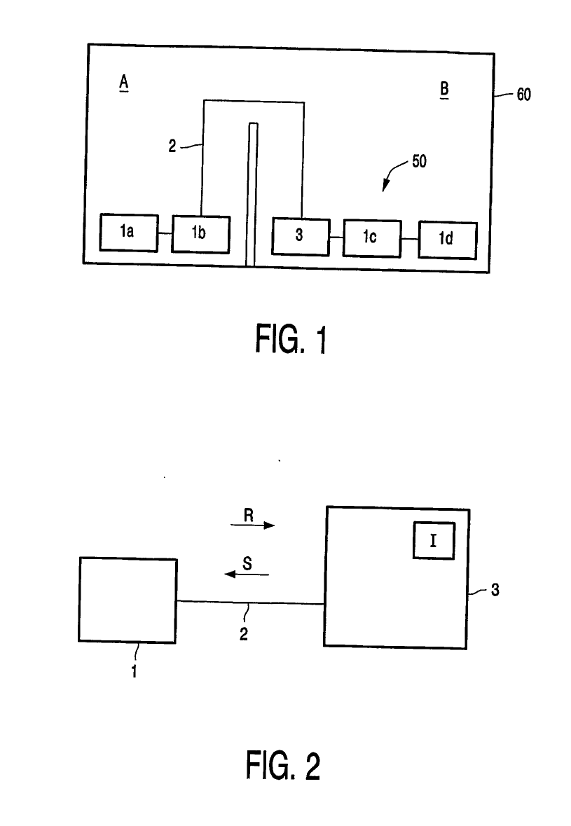

FIG. 1 schematically shows a building in which a system according to the present invention is located.

FIG. 2 schematically shows the production of a sound share according to the present invention.

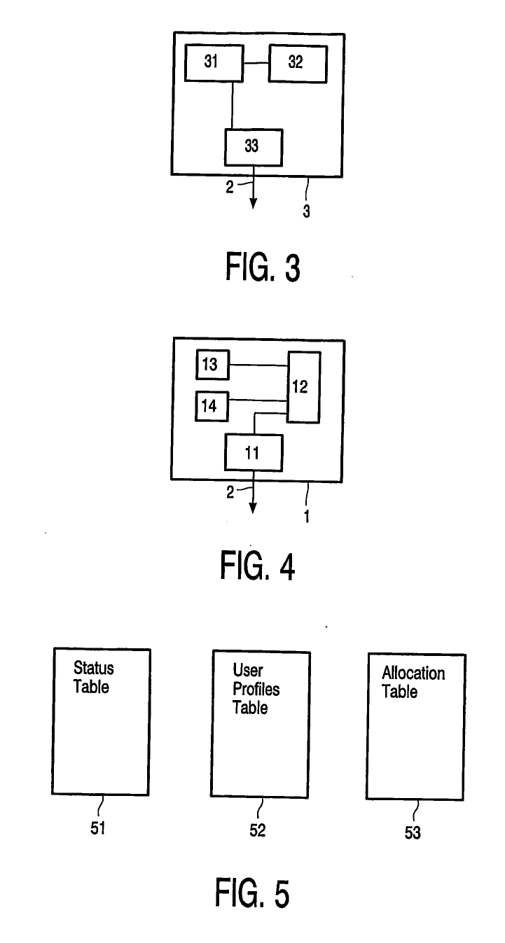

FIG. 3 schematically shows an embodiment of a control unit according to the present invention.

FIG. 4 schematically shows an embodiment of a sound producing device according to the present invention.

FIG. 5 schematically shows tables used in the present invention.

The system 50 shown merely by way of non-limiting example in FIG. 1 comprises a number of consumer devices 1 (1a, 1b, 1c, . . . ) located in a building 60. A network 2 connects the devices 1 to a central control unit 3. The consumer devices may, for example, be a television set 1a, a music center (stereo set) 1b, a telephone 1c and an intercom 1d, all of which may produce sound at a certain point in time.

Although in this particular example the devices are consumer devices for home use, the present invention is not so limited and other types of sound producing devices may also be used in similar or different settings, such as computers (home or office settings), microwave ovens (home, restaurant kitchens), washing machines (home, laundries), public announcement systems (stores, railway stations, airports), music (stereo) sets (home, stores, airports, etc.) and other sound producing devices. Some of these devices may produce sounds both as a by-product of their activities and as an alert, for example washing machines which first produce motor noise and then an acoustic ready signal.

The television set I a shown in FIG. 1 is provided with a network adaptor for interfacing with the network 2, as will later be explained in more detail with reference to FIG. 4. This enables the television set 1a to exchange information with the control unit 3, and possibly with the other devices 1b, 1c and 1d, thus allowing the sound output of the various devices to be coordinated. The network may be a hard-wired network, as shown in FIG. 1, or a wireless network, for example one using Bluetooth® technology. Although in the embodiment of FIG. 1 a single, central control unit 3 is used, it is also possible to use two or more control units 3, possibly even one control unit 3 for every device 1 (1a, 1b, . . . ). In that case each control unit 3 may be accommodated in its associated device 1. Multiple control units 3 exchange information over the network 2.

The devices are in the present example located in two adjacent rooms A and B, which may for example be a living room and a kitchen, with the television set 1a and the music center 1b being located in room A and the other devices being located in room B. When the television set 1a is on, it will produce sound (audio) which normally can be heard, if somewhat muffled, in room B. This sound will therefore interfere with any other sound produced by one of the other devices, and vice versa: the ringing of the telephone 1c will interfere with the sound of the television set 1a.

In accordance with the present invention, the sound production of the various devices is coordinated as follows. Assume that the television set 1a is on and that it is producing sound having a certain sound volume. Further assume that the music center 1b is switched on. The music center 1b then sends a sound request R, via the network 2, to the control unit 3, as is schematically shown in FIG. 2. In response to this sound request, the control unit 3 produces a sound share S on the basis of sound information I stored in the control unit 3.

The sound information I may comprise permanent information, such as the acoustic properties of the respective rooms, their exposure to street noise (window positions) and the location of the devices within the rooms and/or their relative distances; semi-permanent information, such as at the various devices and user preferences; and transient information, such as the status (on/off) of the devices and the sound volume produced by them. The semi-permanent information may be updated regularly, while the transient information would have to be updated each time before a sound share is issued. The user preferences typically include maximum sound levels which may vary during the day and among users. Additional maximum sound levels may be imposed because of the proximity of neighbors, municipal bye-laws and other factors.

The devices 1a-1d of FIG. 1 should together not produce any sound exceeding said maximum sound level. In addition, any ambient noise should be taken into account when determining the total sound production. In the above example of the music center 1b being switched on while the television set 1a was already playing, the sound produced by the television set la and music center 1b, plus any noise, should not exceed the maximum sound level. If the maximum sound level in room A at the time of day concerned is 60 dBA while the television set 1a is producing 35 dBA and the background noise in room A is 10 dBA, the remaining “sound space” is approximately 25 dBA, the background noise level being negligible relative to the sound level of the television set. In other words, the sound share that could be allocated to the music center 1b would involve a maximum sound level of 25 dBA. The user preferences, however, could prevent this maximum sound level being allocated as they could indicate that the television set and the music center should not be producing sound simultaneously. In that case, the sound space allocated to the music center could be “null” or void, and consequently the music center would produce no sound.

The user preferences could also indicate a minimum volume “distance”, that is a minimum difference in volume levels between various devices, possibly at certain times of the day. For example, when a user is watching television she may want other devices to produce at least 20 dBA less sound (at her location) than the television set, otherwise she wouldn't be able to hear the sound of the television set. In such a case allocating a sound share to the television set may require decreasing the sound shares of one or more other devices, in accordance with any priorities assigned by the user.

When the telephone 1c receives an incoming call, it also submits a sound request to the control unit 3. The information stored in the control unit 3 could reflect that the telephone 1c has priority status. This priority status could be part of the user data as some users may want to grant priority status to the telephone, while other user may not. On the basis of the priority status the control unit 3 may alter the sound share allocated to the television set 1a, reducing its maximum volume. This new sound share is communicated to the television set, and then a sound share is allocated to the telephone set, allowing it to ring at a certain sound volume.

The intercom 1d may receive an incoming call at the time the telephone is ringing or about to start ringing. The user preferences may indicate that the intercom has a higher priority status than the telephone, for example because the intercom is used as a baby watch. For this purpose, multiple priority status levels may be distinguished, for instance three or four different priority levels, where the allocated sound space of a device having a lower priority status may be reduced for the benefit of a device having a higher priority status.

A control unit 3 is schematically shown in FIG. 3. In the embodiment shown, the control unit 3 comprises a processor 31, an associated memory 32 and a network adaptor 33. The network adaptor 33 serves to exchange information between the control unit 3 and the network 2. The processor 31 runs suitable software programs allowing it to act as a resource allocator, allocating sound space to the various sound producing devices connected to the network. The memory 32 contains several tables, such as a status table, a user profiles table and a sound space allocation table. These tables are schematically depicted in FIG. 5.

The status table 51 may substantially correspond with the sound status table I shown in FIG. 2 and may contain data relating to the actual status of the devices, such as their current level of sound production, their current level of activity (on/off/standby), and their local ambient (background) noise level. The user profiles table 52 may contain data relating to the preferences of the user or users of the system 50, such as maximum sound levels at different times during the day and at different dates, and priority levels of various devices. The maximum sound levels may be differentiated with respect to frequency ranges. The allocation table 53 contains data relating to the allocated sound shares, that is, the sound volumes allocated to various devices. These sound shares may be limited in time and frequency range. For example, a sound share could be allocated to the music center 1b of FIG. 1 allowing music to be played at a maximum level of 65 dBA from 8 p.m. to 11 p.m., whereas another sound share could allow the same music center 1b to play music at a maximum level of 55 dBA from 11 p.m. to midnight. This second sound share might contain a limitation as to frequencies, for example allowing frequencies above 50 Hz only, thus eliminating any low bass sounds late in the evening.

When allocating sound shares, the control unit 3 takes into account the sound request(s), the status table 51, the user profiles table 52, and the allocation table 53. The status table 51 contains the actual status of the devices 1 while the user profiles table 52 contains user preferences. The allocation table 53 contains information on the sound shares allocated to the various devices 1.

On the basis of the information contained in the tables 51-53 a sound share will be allocated to the device submitting the sound request. Typically this is the largest possible sound share, the “largest” implying, in this context, the maximum allowable sound level with the smallest number of limitations as to time, frequency range, etc. It is, however, also possible to allocate “smaller” sound shares so as to be able to grant subsequent sound requests without the need for reducing any sound shares which have already been allocated.

In accordance with the present invention, sound shares can be limited in time: they may be allocated for a limited time only and expire when that time has elapsed. Alternatively, or additionally, sound shares may be indefinite and are valid until altered or revoked by the control unit.

The status table 51 could further contain information indicating whether the sound production of a device could be interrupted. Various levels of “interruptibility” could suitably be distinguished. The interruption of the sound production of, for example, a vacuum cleaner necessarily involves an interruption of its task. The sound production (ring tone) of a mobile telephone, however, can be interrupted as the device has alternative ways of alerting its user, for instance by vibrations. It will be understood that many other devices can offer alternatives to sound, such as light (signals) and vibrations.

In addition, the status table 51 could contain information relating to the maximum possible sound production of each device, thus distinguishing between the sound production of a mobile telephone and that of a music center.

The user preference table 52 can be modified by users, preferably using a suitable interface, for example a graphics interface program running on a suitable computer. The user interface may advantageously provide the possibility of entering maximum sound levels for various locations (e.g. rooms), times of the day and dates on which these maximum sound levels apply, possibly included or excluded frequency ranges, and other parameters. Additionally, the user may indicate a minimum volume “distance” between devices to avoid disturbance, that is a minimum difference in sound volumes. The user interface may comprise an interactive floor plan of the building indicating the status of the system, for example, the location of the various devices, the noise levels in the rooms, the sound volume produced by the devices, the sound space available in each room and/or at each device, and possibly other parameters that may be relevant. The user interface program may run on a commercially available personal computer having input means, such as a keyboard, and output means, such as a display screen.

Various sound share allocation techniques may be used. Preferably resource allocation techniques are borrowed from the field of computer science, in particular memory management algorithms. Examples of such techniques include, but are not limited to, “fixed partitions”, “variable partitions”, “next fit”, “worst fit”, “quick fit”, and “buddy system”, and are described in commonly available textbooks on operating systems, such as “Modern Operating Systems” by Andrew S. Tanenbaum, Prentice Hall, 2001.

The exemplary embodiment of the device 1 schematically shown in FIG. 4 comprises a network adaptor 11, a core section 12, a loudspeaker 13 and an optional microphone 14. The core section 12, which carries out the main functions of the device, will vary among devices and may in some instances contain a sound producing element such as an electric motor. Typically, the core section 12 will comprise a control portion containing a microprocessor and an associated memory which control the sound output of the device in accordance with the sound share data received via the network 2. The core section will typically also contain a timing mechanism to match a sound share with the time and/or date. The loudspeaker 13 allows the device 1 to produce sound, which may be continuous sound (such as music) or non-continuous sound, such as an alert signal. The network adaptor 11, which may be a commercially available network adaptor, provides an interface between the device 1 and the network 2 and enables the device I to communicate with the control unit 3 and/or other devices. The microphone 14 allows ambient noise to be sensed and measured. The level of ambient noise is advantageously communicated to the control unit (3 in FIG. 1) where it may be stored in status table 51 (FIG. 5).

The microphone 14 may also be used to determine the actual sound shares used by the various devices. Thus the microphone(s) 14 of one or more devices (e.g. 1b) located near another device (e.g. 1a) could be used to determine the actual sound output of the latter device. This measured sound output could then be transmitted to the control unit for verifying and updating its status table 51 and allocation table 53.

The device 1 is arranged in such a way that it produces a sound request prior to producing sound and that it cannot substantially produce sound in the absence of a valid sound share. It is further arranged in such a way that it is substantially incapable of producing sound which exceeds its current valid sound share. This also implies that sound production will cease when any time-limited sound share has expired. These controls are preferably built-in in the control portion of the core section 12 of FIG. 4.

The network 2 of FIG. 1 suitably is a home network using middle ware standards such as UPnP, Jini and HAVi which allow a person skilled in the art a straightforward implementation of the present invention. Other types of networks may, however, be used instead. It is noted that the network 2 is shown in FIGS. 1 and 2 as a wired network for the sake of clarity of the illustration. However, as mentioned above, wireless networks may also be utilized. The network 2 advantageously connects all devices that are within each other's “acoustic vicinity”, that is, all devices whose sound production may interfere. The sound output of any devices in said “acoustic vicinity” which are not connected to the network 2 may be taken account of by background noise measurements.

The present invention is based upon the insight that the maximum amount of sound at a certain location and at a certain point in time is a scarce resource as many devices may be competing to fill this “sound space”. The present invention is based upon the further insight that parts or “sound shares” of this “sound space” may be allocated to each device. The present invention benefits from the further insight that the allocation of “sound shares” should be based upon sound status information including but not limited to the sound volume produced by the various devices.

It is noted that any terms used in this document should not be construed so as to limit the scope of the present invention. In particular, the words “comprise(s)” and “comprising” are not meant to exclude any elements not specifically stated. Single elements may be substituted with multiple elements or with their equivalents.

It will be understood by those skilled in the art that the present invention is not limited to the embodiments illustrated above and that many modifications and additions may be made without departing from the scope of the invention as defined in the appending claims.

1. A method of controlling the audio output of a first and at least one second device capable of producing sound, which devices (1a, 1b, . . . ) are capable of exchanging information with a control unit (3), the method comprising the steps of:
the control unit gathering sound status information (I) on at least the second devices;
the first device, prior to increasing its sound production, submitting a sound production request (R) to the control unit;
the control unit, in response to the request, allocating a sound share (S) to the first device; and
the first device producing sound in accordance with the allocated sound share, wherein the sound status information (I) comprises the volume of the sound produced by the respective device, and wherein the sound share (S) involves a maximum permitted sound volume.

2. The method according to claim 1, wherein the sound status information further comprises at least one of an ambient noise level, at least one user profile and a frequency range.

3. The method according to claim 1, wherein the sound share further involves at least one of a time duration and a frequency range.

4. The method according to claim 1 wherein the first device uses an alternative output when the allocated sound share is insufficient, the alternative output preferably involving vibrations and/or light.

5. The method according to claim 1, wherein at least one device may have a priority status, and wherein an allocated sound share may be adjusted in response to a sound request from a device having priority status.

6. The method according to claim 1, wherein the devices are connected by a communications network, preferably a wireless communications network.

7. The method according to claim 1, wherein each device is provided with an individual control unit.

8. The method according to claim 1, wherein user preferences are entered in the control unit (3) via a user interface.

9. A system for use in the method according to claim 1, the system (50) comprising a first and at least one second device capable of producing sound, which devices (1a, 1b, . . . ) are capable of exchanging information with a control unit (3), the system being arranged for:
the control unit gathering sound status information (I) on at least the second devices;
the first device, prior to increasing its sound production, submitting a sound production request (R) to the control unit;
the control unit, in response to the request, allocating a sound share (S) to the first device; and
the first device producing sound in accordance with the allocated sound share, wherein the sound status information (I) comprises the volume of the sound produced by the respective device, and wherein the sound share (S) involves a maximum permitted sound volume.

10. A control unit (3) for use in the method according to claim 1, the control unit comprising a processor (31), a memory (32) associated with the processor and a network adapter (33), wherein the processor is programmed for allocating sound shares (S) to devices in response to sound requests.

11. The control unit according to claim 10, wherein the processor is additionally programmed for maintaining a device status table (51) and a user profiles table (52), and a sound shares allocation table (53).

12. A software program for use in the control unit according to claim 10.

13. A data carrier comprising the software program according to claim 12.
